(19) United States
(12) Patent Application Publication
(10) Pub. No.: US 2012/0207331 A1
(43) Pub. Date: Aug. 16, 2012

(54) PREAMPLIFIER CIRCUIT AND MICROPHONE HAVING THE SAME

(75) Inventor: Weiliang HU, Kanagawa (JP)

(73) Assignee: RENESAS ELECTRONICS CORPORATION, Kanagawa (JP)

(21) Appl. No.: 13/364,356

(22) Filed: Feb. 2, 2012

(30) Foreign Application Priority Data
Feb. 14, 2011 (JP) 2011-028529

(51) Int. Cl. H03F 99/00; H03F 3/45

(52) U.S. Cl. 381/120; 330/253

(57) ABSTRACT

A preamplifier has first and second PMOS transistors each functioning as a source follower. Furthermore, the preamplifier circuit has third and fourth PMOS transistors functioning in pairs as a differential amplifier. A gate of the first transistor and a gate of the fourth transistor are coupled together through a second variable capacitor. A gate of the second transistor and a gate of the third transistor are coupled together through a first variable capacitor. A source of the first transistor and a drain of the third transistor are coupled together. A source of the second transistor and a drain of the fourth transistor are coupled together. A source of the third transistor and a source of the fourth transistor are coupled together.

### CROSS-REFERENCE TO RELATED APPLICATIONS

The disclosure of Japanese Patent Application No. 2011-28529 filed on Feb. 14, 2011 including the specification, drawings and abstract is incorporated herein by reference in its entirety.

### BACKGROUND

The present invention relates to a preamplifier circuit and a microphone having the preamplifier circuit.

### Electret Condenser Microphone (ECM)

For preamplifier circuits used for microphones, such as an electret condenser microphone, it is desirable to have high input impedance and low output impedance characteristics. A source follower circuit is a simple configuration that satisfies these characteristics. Therefore, the source follower circuit is widely used as the preamplifier circuit.

Japanese Unexamined Patent Application Publication No. 2006-245740 discloses a technology about an amplifier circuit that can be miniaturized and an electret condenser microphone using this. FIG. 6 shows a configuration of the electret condenser microphone. This electret condenser microphone has an impedance element (J-FET) 11 and a high resistance element 12 that is coupled to an input of the impedance variable element 11 and biases the input. The high resistance element 12 is made up by serially coupling a P-channel MOS transistor and an N-channel MOS transistor both of which are formed on the same semiconductor substrate. This configuration realizes high input impedance and low output impedance characteristics.

Japanese Unexamined Patent Application Publication No. 2000-101923 discloses a technology about a source follower type circuit having a gain correction function. FIG. 7 shows a configuration of the circuit. The circuit is equipped with a load control voltage varying part 22 in addition to a source follower 21. The load control voltage varying part 22 includes NMOS transistors M3 and M4, a capacitor C1, and a resistor R1. A set of the NMOS transistors M3 and M4 operates as one inverter. The load control voltage varying part 22 feeds back its output signal to a gate of a load transistor M2 of the source follower 21 to provide feedback. In detail, the load control voltage varying part 22 varies the load current that follows passing through the load transistor M2 of the source follower 21 in a reverse direction with respect to variations of the input voltage and the output voltage. Since this decreases or increases the load current so that it may correspond to the input/output voltage, the output voltage increases or decreases. Therefore, an AC gain of the source follower can be increased.

Japanese Unexamined Patent Application Publication No. 2010-206356 discloses one mode about a preamplifier circuit. In this preamplifier circuit, a differential amplifier is made up by using two transistors as a differential pair in an amplifier mode. In the preamplifier circuit, each of the two transistors makes up a source follower in a reset mode. The preamplifier circuit aims at increasing a response characteristic even when an abrupt change occurs in an amplitude of the input voltage signal.

Japanese Unexamined Patent Application Publication No. 2009-10640 discloses a technology about a signal conversion device capable of enlarging a gain in a cooperation region. In order to process a voltage signal of a wide range of input amplitude, the signal conversion device is configured to combine a source follower and a differential amplifier circuit.

### SUMMARY

A voltage gain of the general source follower circuit represented by description of Japanese Unexamined Patent Application Publication No. 2006-245740 becomes like the following formula (Formula 1). Incidentally, in the following formula, a mutual conductance of the input transistor shown in FIG. 6 is denoted by gm1 and an output load (corresponding to R1 of FIG. 1) of the source follower is denoted by Rout.

$${A}_{amp} = \frac{{gm}_{1} \cdot {R}_{out}}{1 + {gm}_{1} \cdot {R}_{out}}$$

As shown in Formula 1, the voltage gain is always a negative gain (less than unity). Microphones including such a source follower circuit come with a problem that an input sensitivity drops because the voltage gain of the source follower circuit is the negative gain. In order to cope with this, it is necessary to enlarge power consumption by enlarging a ratio of the gate width and the gate length (W/L) of the transistor (in FIG. 6, J-FET 11). However, since the size of the transistor was affected by influences of flicker noise and an input capacitance, an optimum value has been decided. Therefore, generally in such a preamplifier circuit, a loss of several decibels occurs, that is, the voltage falls. If the loss arises in this preamplifier circuit, noise of an amplifier etc. provided in the latter stage of the preamplifier circuit cannot be suppressed. Therefore, an SNR (Signal Noise Rate) as a microphone deteriorates, and an input sensitivity characteristic becomes worse in connection with this.

A technology of Japanese Unexamined Patent Application Publication No. 2000-101923 provides a configuration that can correct a gain of the source follower circuit. However, as shown in FIG. 7, the inside of a load control voltage varying part 22 is an inverter configuration (M3 and M4). Here, M4 is an NMOS transistor whose flicker noise characteristic is worse than that of a PMOS transistor. Therefore, the noise characteristic of the load control voltage varying part 22 affects a source follower 21. As a result, the noise characteristic of the entire circuit will deteriorate.

In addition, there is no concrete suggestion about the gain control in the preamplifier circuits in Patent documents 3 and 4.

That is, it was difficult for the above-mentioned technology to realize the preamplifier circuit having a low noise characteristic and a microphone using the preamplifier circuit

According to one aspect of the present invention, a preamplifier circuit includes first and second transistors that function as source followers, and third and fourth transistors that function in pairs as a differential amplifier, a gate of the first transistor and a gate of the fourth transistor being coupled through a first capacitor, a gate of the second transistor and a gate of the third transistor being coupled through a second capacitor, a source of the first transistor and a drain of the third transistor being coupled, a source of the second transistor and a drain of the fourth transistor being coupled, and a source of the third transistor and a source of the fourth transistor being coupled.

In the aspect of the present invention, since the first and second transistors function as source followers, impedance transformation can be realized. Furthermore, since the preamplifier circuit is configured to be able to add an output of the source follower of the first transistor and an output that the third transistor amplifies, it can obtain a gain with a positive value. Similarly, since the preamplifier circuit is configured to be able to add an output of the source follower of the second transistor and an output that the fourth transistor amplifies, it can obtain a gain with a positive value. Thereby, a preamplifier circuit having the low noise characteristic can be realized.

According to the aspect of the present invention, the preamplifier circuit having the low noise characteristic and a microphone using the preamplifier circuit can be provided.

### BRIEF DESCRIPTION OF THE DRAWINGS

FIG. 1 is a diagram showing a configuration of a preamplifier circuit according to a first embodiment;

FIG. 2 is a diagram showing a configuration of a preamplifier circuit according to a second embodiment;

FIG. 3 is a diagram showing a configuration of a preamplifier circuit according to a third embodiment;

FIG. 4 is a diagram showing a configuration of a microphone to which the preamplifier circuit according to any one of the first to third embodiments is applied;

FIG. 5 is a diagram showing a configuration of a digital microphone to which the preamplifier circuit according to any one of the first to third embodiments is applied;

FIG. 6 is a diagram showing a configuration of an electret condenser microphone according to Japanese Unexamined Patent Application Publication No. 2006-245740; and

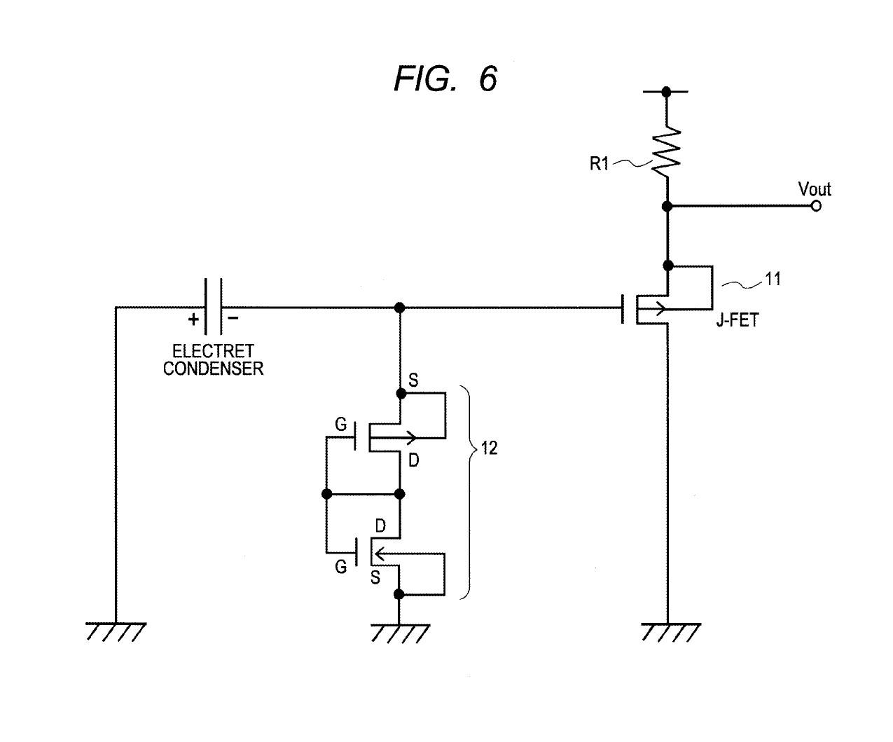

FIG. 7 is a diagram showing a configuration of a source follower type circuit according to Japanese Unexamined Patent Application Publication No. 2000-101923.

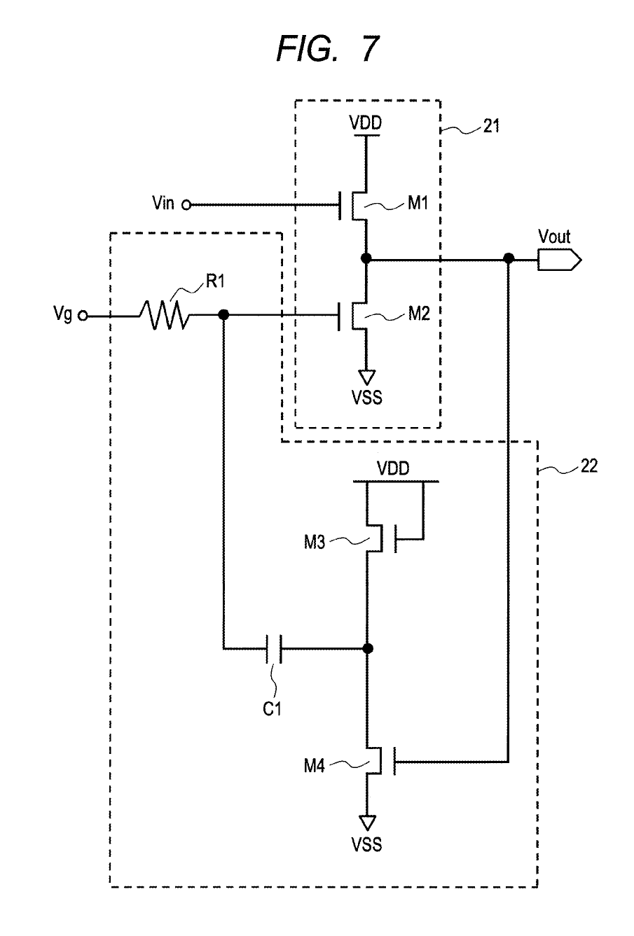

### DETAILED DESCRIPTION

### First Embodiment

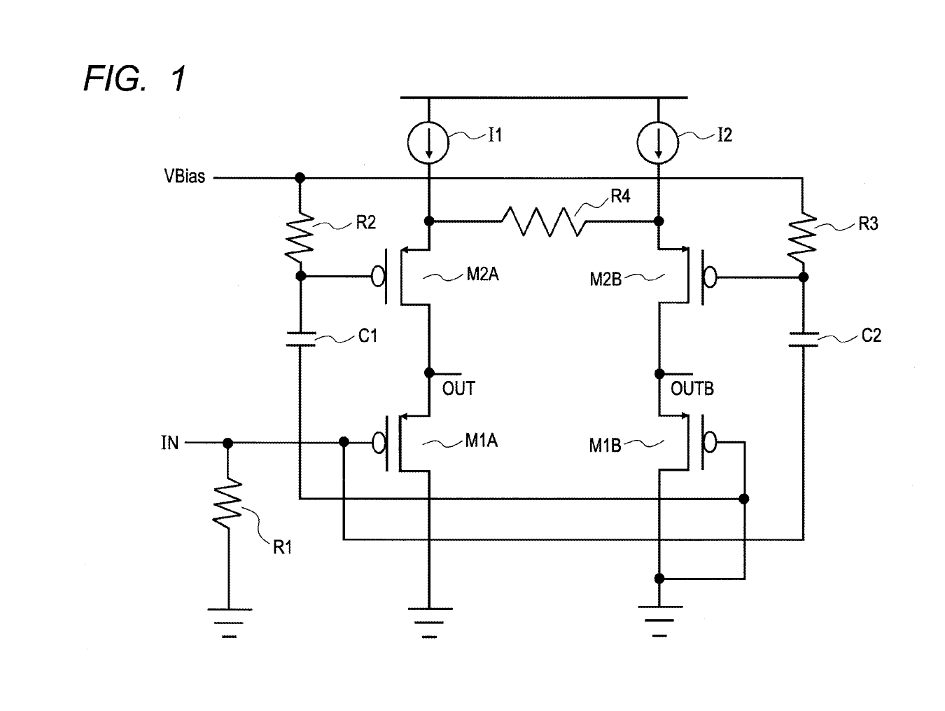

Hereafter, an embodiment of the present invention will be described with reference to drawings. FIG. 1 is a diagram showing a configuration of a preamplifier circuit according to this embodiment. A microphone signal IN (also described as a voltage signal IN) is inputted into the preamplifier circuit. The preamplifier circuit includes PMOS transistors M1A, M1B, M2A, and M2B, resistors R1 to R4, current sources I1, I2, and variable capacitors C1, C2. Moreover, a bias voltage VBias is supplied from a bias circuit (not illustrated). This makes below-mentioned PMOS transistors M2A and M2B biased.

The PMOS transistor M1A functions as a core transistor of the source follower. The voltage signal IN is supplied to a gate of M1A. The gate of M1A is coupled to a gate of M2B through the variable capacitor C2. A source of M1A is cascode coupled with a drain of M2A. A drain of M1A is coupled with a grounding voltage terminal GND. An output voltage signal of the source follower is supplied to an output terminal OUT from the source of M1A.

The PMOS transistor M1B functions as a core transistor of the source follower. A gate of M1B is coupled with a gate of M2A through the variable capacitor C1. A source of M1B is cascode coupled with a drain of M2B. A drain of M1B is coupled with the grounding voltage terminal GND. The output voltage signal of the source follower is supplied to an output terminal OUTB from the source of M1B.

The sources of the PMOS transistors M2A and M2B are coupled together through the resistor R4. Thereby, the transistors M2A and M2B operate as a differential amplifier.

The gate of M2A is coupled with the gate of M1B through the variable capacitor C1. The drain of M2A is coupled with the output terminal OUT. The transistor M2A amplifies an amplitude of a voltage signal that is outputted from the gate of M1B and is inputted thereinto from the gate of M2A, and outputs it from its drain to the output terminal OUT. Here, the voltage signal inputted into the gate of M2A is in a phase-reversal relationship (phases differ by 180 degrees) with respect to an input voltage signal IN inputted into the gate of M1A. Details will be described later. Amplification by M2A changes the phase of the voltage signal inputted into the gate of M2A by 180 degrees. Thereby, the signals of an identical phase are supplied to the output terminal OUT from the drain of M1A and the drain of M2A, respectively.

The gate of M2B is coupled with the gate of M1A through the variable capacitor C2. The drain of M2B is coupled with the output terminal OUTB. M2B amplifies the amplitude of the voltage signal that was outputted from the gate of M1A and is inputted into the gate of M2B, and outputs it to the output terminal OUTB from its drain. Here, the voltage signal inputted into the gate of M2B is in a phase-reversal relationship to the voltage signal inputted into the gate of M1B (phases differ by 180 degrees). Details will be described later. Amplification by M2B changes the phase of the voltage signal inputted into the gate of M2B by 180 degrees. Thereby, the voltage signals of the identical phase are supplied to the output terminal OUTB from the drain of M1B and the drain of M2B, respectively.

The DC-cut capacitor C1 is provided between the gate of M2A and the gate of M1B. Similarly, the DC-cut capacitor C2 is provided between the gate of M1A and the gate of M2B. The capacitors C1 and C2 cut direct-current components, respectively.

The current source I1 supplies a current to a source of M2A and also supplies a current to a source of M2B through the resistor R4. The current source I2 supplies a current to the source of M2B and also supplies a current to the source of M2A through the resistor R4.

Following this, an operation of the preamplifier circuit according to this embodiment will be explained. The voltage signal IN is inputted into the gate of M1A. At substantially the same time as this, a voltage signal in a phase-reversal relationship to the voltage signal IN is inputted into the gate of M2A from the gate of M1B through the variable capacitor C1. Below, phase relationships of these signals will be explained.

When the voltage of the voltage signal IN rises, the gate voltage of M1A rises. The voltage of the source of M1A also rises with the rise of the gate voltage of M1A. Thereby, since the voltage of a differential output signal of the output terminal OUT also rises, the amount of current supplied to the source of M2A increases, and the amount of current supplied to the source of M2B decreases. Therefore, the voltage signal outputted from the gate of M1B lowers. That is, the voltage signal (voltage signal inputted into the gate of M2A) outputted from the gate of M1B have an inverse relationship to the voltage signal IN.

The phase-reversal voltage signal inputted into the gate of M2A is amplified by M2A, and is outputted from the drain of M2A. At this time, a phase changes by 180 degrees (it is reversed) by an amplification processing of M2A.

In the output terminal OUT, the voltage signal inputted from the source of M1A and the voltage signal inputted from the drain of M2A are added being in phase.

The voltage signal IN is inputted into the gate of M2B at substantially the same timing as the gate of M1A. At substantially the same time as this, a voltage signal being in a phase-reversal relationship to the voltage signal IN is inputted into the gate of M1B from the gate of M2A through the variable capacitor C1.

The voltage signal inputted into the gate of M2B is amplified by M2B, and is outputted from the drain of M2B. At this time, an amplification processing of M2B changes its phase by 180 degrees (it is reversed). That is, the outputted signal becomes in a phase-reversal relationship to the input voltage signal IN.

In the output terminal OUTB, the voltage signal inputted from the source of M1B and the voltage signal inputted from the drain of M2B are added in phase. Here, both voltage signals added are in a phase-reversal relationship to the input voltage signal IN. For this reason, the output of the output terminal OUT and the output of the output terminal OUTB are in a phase-reversal relationship.

Following this, a voltage gain of the preamplifier circuit according to this embodiment will be explained. In the case where a resistance value of the resistor R4 is assumed to be zero, the voltage gain at the output terminal OUT is shown by the following formula (Formula 2).

$${A}_{amp} = \frac{( {gm}_{1} + {gm}_{2} ) \cdot {R}_{out}}{1 + {gm}_{1} \cdot {R}_{out}}$$

Incidentally, gm1 is a mutual conductance of M1A and M1B. gm₂ is a mutual conductance of M2A and M2B. Rout is a total value of source-drain resistances of M2B and M1B and an input impedance of a next stage amplifier (not illustrated). Since the amplified voltage signal is supplied to the output terminal OUTB from the drain of M2A, the voltage gain becomes as represented by the above-mentioned formula. By adjusting gm₁ and gm₂, the voltage gain Aamp can be made larger than unity. That is, a positive gain is realizable. Adjustment of gm₁ and gm₂ can be performed by adjusting a transistor size.

The voltage gain in the output terminal OUTB is also represented by the above-mentioned formula (Formula 2). However, since the gate of M1B is coupled to the ground in the configuration of FIG. 1 and a voltage value of the voltage signal inputted into the gate of M2A is small, an amplitude of the signal supplied to the output terminal OUT is small compared with an amplitude of an output signal of the output terminal OUTB. Since the input signal of the IN terminal is amplified with its phase reversed, the amplitude of the signal supplied to the output terminal OUTB is large compared with an amplitude of an output signal of the output terminal OUT.

M1A and M2A each have a conversion function of impedance because they operate as source followers. Furthermore, since the current sources (I1, I2) are shared by M1A, M2A, M1B, and M2B, the above-mentioned formation of positive gain and the conversion function of impedance can be realized without increasing power consumption.

Moreover, all of M1A, M2A, M1B, and M2B are made up of PMOS transistors. The PMOS transistors have a better Flicker noise characteristic than the NMOS transistors. For this reason, a preamplifier circuit with an excellent noise characteristic is realizable with them.

As described above, the preamplifier circuit according to this embodiment is specified to have a single input of the input voltage signal IN that is assumed to come from a microphone, and to output a differential signal. This enables the preamplifier circuit to be coupled with a differential buffer amplifier etc. in its later stage.

Incidentally, although in the example of FIG. 1, the source of M2A and the source of M2B are coupled together through the resistor R4, it is not necessarily required to be coupled in this way. For example, the source of M2A and the source of M2B may be directly coupled by wiring. Alternatively, the source of M2A and the source of M2B may be coupled through a MOS transistor.

Incidentally, although the gate of M1B is coupled with the ground in FIG. 1, the configuration is not necessarily restricted to this, and the gate of M1B may be not coupled with the ground.

### Second Embodiment

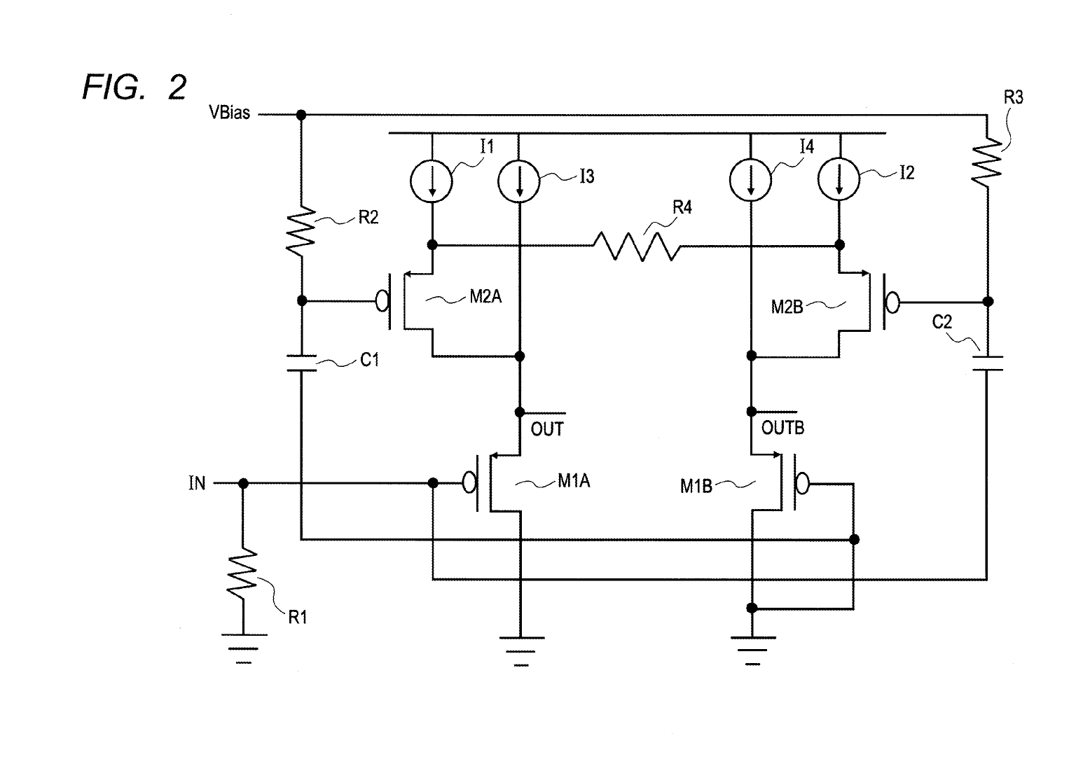

A preamplifier circuit according to this embodiment is characterized by providing a current source directly coupled to transistors operating as source followers. With reference to FIG. 2, a point of the preamplifier circuit according to this embodiment that is different from the first embodiment will be explained. Incidentally, the components given the same reference numerals as those of FIG. 1 perform equivalent operations of those of FIG. 1, unless it is specially described.

The preamplifier circuit according to this embodiment is equipped with current sources I3 and I4 in addition to the configuration of the preamplifier circuit of the first embodiment. The current source I3 is coupled with the source of M1A. The current source I4 is coupled with the source of M1B. Other configurations are the same as those of the first embodiment.

With the above-mentioned configuration, even in a case where degradation of the current source I1, etc. arises temporarily, a current is supplied to M1A from the current source I4 in addition to the current source I1. Thereby, effects, such as variation compensation, can be attained.

### Third Embodiment

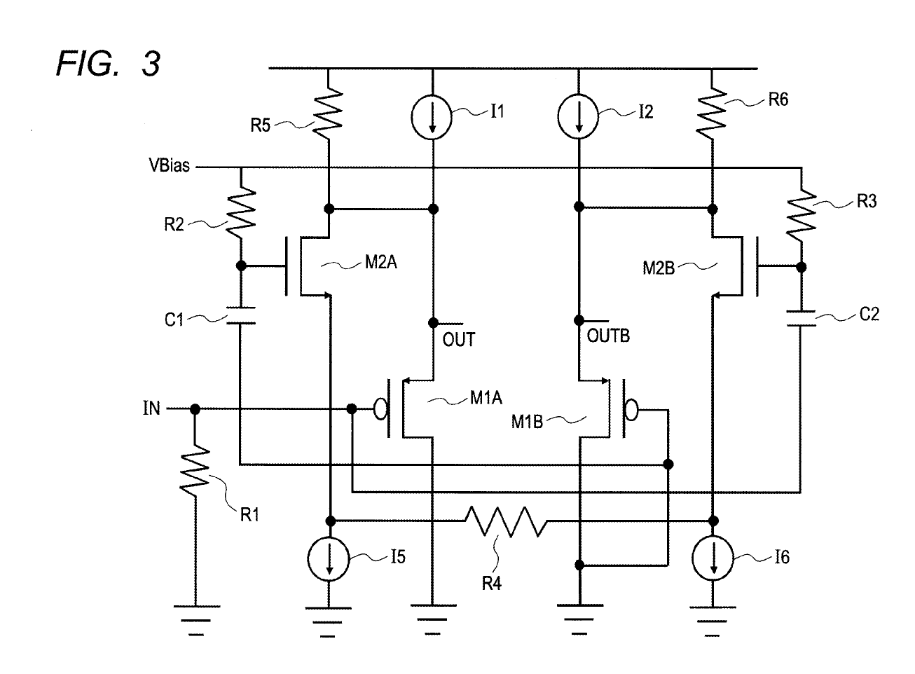

A preamplifier circuit according to this embodiment is characterized by that each of M2A and M2B operating as a differential amplifier is made up of an NMOS transistor. With reference to FIG. 3, a point of the preamplifier circuit according to this embodiment that is different from the first and second embodiments will be explained. Incidentally, in FIG. 3, components given the same reference numerals as those of FIG. 1 perform operations equivalent to those of FIG. 1, unless it is specially described.

M2A and M2B are NMOS transistors, and operate as a differential amplifier. The drain of M2A is coupled with the current source I1 and one end of a resistor R5. The drain of M2B is coupled with the current source I2 and one end of a resistor R6. Coupling relationships of the sources, the drains, and the gates of M1A, M2A, M1B, and M2B are the same as those of FIG. 1.

As described above, even with a configuration of making the NMOS transistors operate as a differential amplifier, the impedance transformation and the formation of positive gain described above are realizable. Moreover, a current from the current source I1 is supplied to M1A not via M2A. Similarly, a current from the current source I2 is supplied to M1B not via M2B. Thereby, compared with the configuration of FIG. 1, lowering voltage becomes possible.

### Example of Application

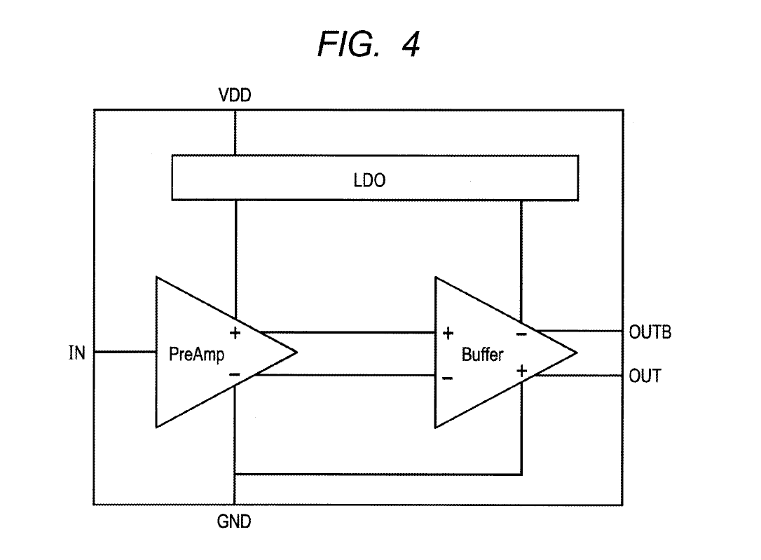

Below, an example of application of the preamplifier circuits according to the above-mentioned first to third embodiments is shown. FIG. 4 is a diagram showing a configuration of a microphone including the preamplifier circuit according to the first to third embodiments.

A preamplifier circuit PreAmp is a preamplifier circuit described in any one of the first to third embodiments. A buffer amplifier Buffer is a buffer amplifier provided in the next stage of the preamplifier circuit PreAmp.

The low dropout regulator LDO is coupled to the preamplifier circuit PreAmp and the buffer amplifier Buffer. The low dropout regulator LDO converts a power supply voltage into a fixed voltage, and supplies it to the preamplifier circuit PreAmp and the buffer amplifier Buffer.

As described above, the voltage gain of the preamplifier circuit according to the first to third embodiments can take the value of unity or more. Therefore, noise of the buffer amplifier Buffer placed in the latter stage of the preamplifier circuit PreAmp can be suppressed. Incidentally, as the above-mentioned microphones, there can be enumerated an electret condenser microphone, a MEMS microphone, etc.

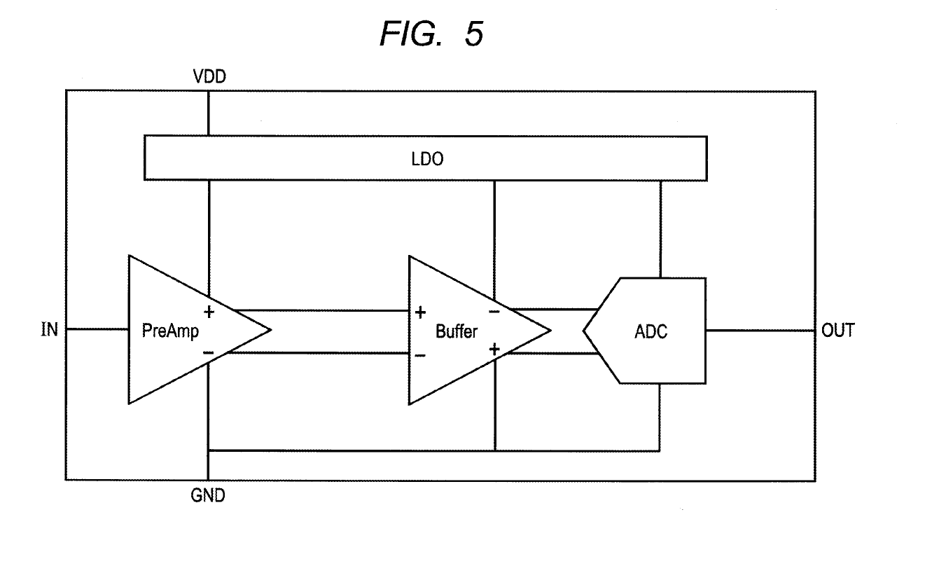

Following this, other examples of application of the preamplifier circuit according to the first to third embodiments will be shown. FIG. 5 is a diagram showing a configuration of a digital microphone including the preamplifier circuit according to any one of the first to third embodiments.

The digital microphone is equipped with an analog-to-digital conversion circuit ADC in the later stage of the buffer amplifier Buffer in addition to the configuration of FIG. 4. The analog-to-digital conversion circuit ADC converts an analog signal inputted from the buffer amplifier Buffer into a digital signal and outputs it to an arbitrary circuit etc. in the latter stage.

As described above, the voltage gain of the preamplifier circuit according to the first to third embodiments can take the value of unity or more. Therefore, the digital microphone shown in FIG. 5 can also have a low noise characteristic.

Note that the present invention is not limited to the above-mentioned embodiments, and can be appropriately modified within a scope not departing from the gist of the present invention.

What is claimed is:

1. A preamplifier circuit comprising:
first and second transistors, each functioning as a source follower; and
third and fifth transistors functioning in pairs as a differential amplifier;
wherein a gate of the first transistor and a gate of the fourth transistor are coupled together through a second capacitor,
a gate of the second transistor and a gate of the third transistor are coupled together through a first capacitor,
a source of the first transistor and a drain of the third transistor are coupled together,
a source of the second transistor and a drain of the fourth transistor are coupled together, and
a source of the third transistor and a source of the fourth transistor are coupled together.

2. The preamplifier circuit according to claim 1,
wherein a resistor is provided between a source of the third transistor and a source of the fourth transistor.

3. The preamplifier circuit according to claim 1,
wherein a fifth transistor is provided between a source of the third transistor and a source of the fourth transistor.

4. The preamplifier circuit according to claim 1,
further comprising a first current source coupled to the first transistor and a second current source coupled to the second transistor.

5. The preamplifier circuit according to claim 1,
wherein the first and fourth transistors are P-channel MOS transistors.

6. The preamplifier circuit according to claim 1,
wherein the first and second transistors are P-channel MOS transistors, and the third and fourth transistors are N-channel MOS transistors.

7. A microphone equipped with the preamplifier circuit according to claim 1.
